(19) United States
(12) Patent Application Publication
(10) Pub. No.: US 2022/0076752 A1
(43) Pub. Date: Mar. 10, 2022

(54) MEMORY DEVICE AND OPERATION METHOD THEREFOR

(71) Applicant: MACRONIX INTERNATIONAL CO., LTD., Hsinchu (TW)

(72) Inventors: Guan-Wei WU, Zhubei City (TW); Yao-Wen CHANG, Zhubei City (TW); I-Chen YANG, Miaoli County (TW)

(21) Appl. No.: 17/015,143

(22) Filed: Sep. 9, 2020

(51) Int. Cl. G11C 16/08; G11C 16/10; G11C 16/26; G11C 16/30; G11C 16/34

(52) U.S. Cl. CPC G11C 16/08; G11C 16/10; G11C 16/3459; G11C 16/30; G11C 16/26

(57) ABSTRACT

Provided is an operation method for a memory device, comprising: preparing to program a target word line; judging whether at least one memory cell of a plurality of memory cells of an adjacent word line is to be programmed to a first target state; and based on whether the at least one memory cell of the memory cells of the adjacent word line is to be programmed to the first target state, determining to program the adjacent word line first or to program the target word line first.

### TECHNICAL FIELD

The disclosure relates in general to a memory device and an operation method therefor.

### BACKGROUND

In a memory device, the programming operations on the adjacent word line WL(N+1) will increase the threshold voltage of the word line WLN, which is called “word line interference”. The main reason of the word line interference is that, the overdrive voltage on the adjacent word line is insufficient. The overdrive voltage VOV is defined as the difference between the gate-source voltage and the threshold voltage of the transistor, which is expressed as; VOV=VGS−VTH.

FIG. 1 (Prior art) shows threshold voltage (VTH) increase caused by word line interference in the prior art. FIG. 1 is the threshold voltage distribution of Triplelevel cells (TLC), wherein “ERS” refers to an erase state. The solid line refers to the threshold voltage distribution on the word line WLN after the word line WLN is programmed; while the dotted line refers to the threshold voltage distribution on the word line WLN after the word line WL(N+1) is programmed, which is caused by the word line interference. By comparing the solid line and the dotted line, the word line interference will increase the threshold voltage distribution. Wider threshold voltage distribution will be negative in judging the readout data.

Thus, how to reduce the word line interference to improve the performance of the memory device is one of the efforts.

### SUMMARY

According to one embodiment, provided is an operation method for a memory device, comprising: preparing to program a target word line; judging whether at least one memory cell of a plurality of memory cells of an adjacent word line is to be programmed to a first target state; and based on whether the at least one memory cell of the memory cells of the adjacent word line is to be programmed to the first target state, determining to program the adjacent word line first or to program the target word line first.

According to another embodiment, provided is an operation method for a memory device, including: preparing to read a target word line; determining whether at least one memory cell of a plurality of memory cells of the target word line is programmed to a target state; and based on whether the at least one memory cell of the memory cells of the target word line is programmed to the target state, applying an original pass voltage or an increased pass voltage to an adjacent word line.

According to one embodiment, provided is a memory device, comprising: a memory array, including a plurality of memory cells and a plurality of word lines; and a controller, coupled to the memory array. The controller is configured for: preparing to program a target word line; judging whether at least one memory cell of a plurality of memory cells of an adjacent word line is to be programmed to a first target state; and based on whether the at least one memory cell of the memory cells of the adjacent word line is to be programmed to the first target state, determining to program the adjacent word line first or to program the target word line first.

### BRIEF DESCRIPTION OF THE DRAWINGS

FIG. 1 (Prior art) shows threshold voltage (VTH) increase caused by word line interference in the prior art.

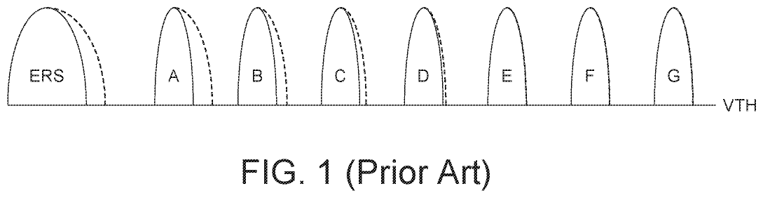

FIG. 2 shows a programming operation method according to one embodiment of the application.

FIG. 3 shows threshold voltage distribution of triplelevel cells according to one exemplary embodiment of the application.

FIG. 4 shows a read operation method according to one embodiment of the application.

FIG. 5 shows threshold voltage distribution of triplelevel cells according to one embodiment of the application.

FIG. 6 shows a functional block of a memory device according to one embodiment of the application.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

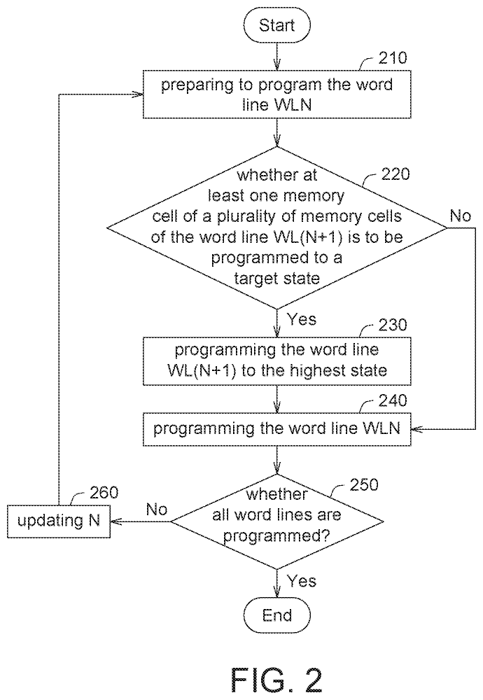

FIG. 2 shows a programming operation method according to one embodiment of the application. In step 210, it is prepared to program a plurality of memory cells of the word line WLN (i.e. a target word line). In step 220, it is determined whether at least one memory cell of a plurality of memory cells of the word line WL(N+1) is to be programmed to the highest state (i.e. a target state). In one embodiment of the application, the memory cells may be implemented by, for example but not limited by, multilevel cells (MLC), Triple-level cells (TLC), or quad-level cells (QLC). Taking TLC as an example, the TLC may be programmed as eight states, i.e. erased state, A state, B state, C state, state, E state, F state and G state. Thus, in this case, the highest state is the G state with highest threshold voltage.

If yes in step 220, in step 230, the memory cells of the word line WL(N+1) are programmed to the highest state.

If no in step 220, in step 240, the memory cells of the word line WLN are programmed (in here, the memory cells of the word line WLN are programmed to one of the A state to the F state, respectively).

In step 250, it is determined whether all word lines are programmed. If yes in step 250, then the flow ends. If no in step 250, then the flow proceeds to step 260. In step 260, N is updated (N=N+1) to program the next word line.

That is, based on whether at least one memory cell of the memory cells of the adjacent word line WL(N+1) is to be programmed to the highest state, it is determined to program the memory cells of the adjacent word line WL(N+1) first or to program the memory cells of the word line WLN first.

In one embodiment of the application, when it is prepared to program the target word line, it is determined whether at least one memory cell of the memory cells of the adjacent word line is to be programmed to a first target state (for example, the highest state). When at least one memory cell of the memory cells of the adjacent word line is to be programmed to the first target state, the memory cells of the adjacent word line is programmed first, and then the memory cells of the target word line is programmed. This is because, in prior art, when at least one memory cell of the memory cells of the adjacent word line is to be programmed to the first target state (for example, a highest state), the programming of the adjacent word line will cause word line interference on the target word line, which is already programmed earlier. Thus, in the embodiment of the application, when at least one memory cell of the memory cells of the adjacent word line is to be programmed to the first target state, the adjacent word line is programmed first and then the target word line is programmed later. By so, the word line interference on the target word line is effectively reduced.

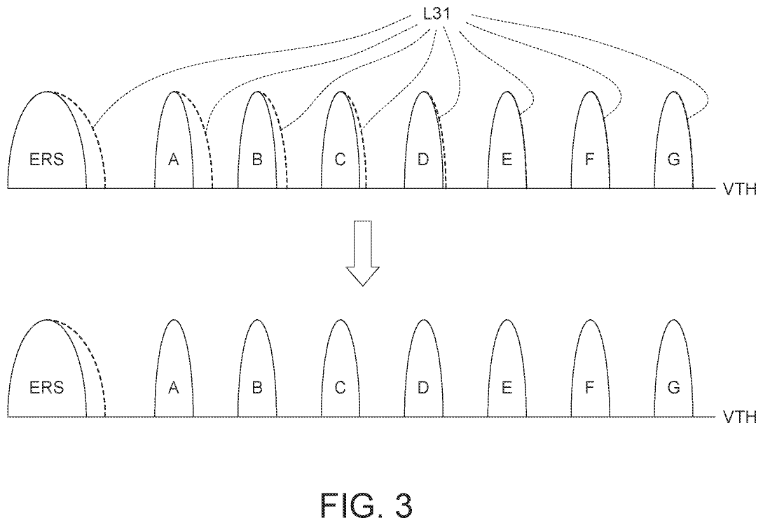

FIG. 3 shows threshold voltage distribution of triplelevel cells according to one embodiment of the application. The upper part in FIG. 3 refers to the threshold voltage distribution in the prior art, wherein the threshold voltage increase of the A state to the F state, caused by the word line interference, are represented by the curve L31. As known, if the threshold voltage is increased, then it is not easy to correctly judge the readout data. The lower part in FIG. 3 refers the threshold voltage distribution in the embodiment of the application. By comparing the upper part and the lower part of FIG. 3, the embodiment of the application may effectively reduce the threshold voltage increase of the A state to the F state which is caused by the word line interference. The narrow threshold voltage distribution is advantageous in correctly judging the readout data.

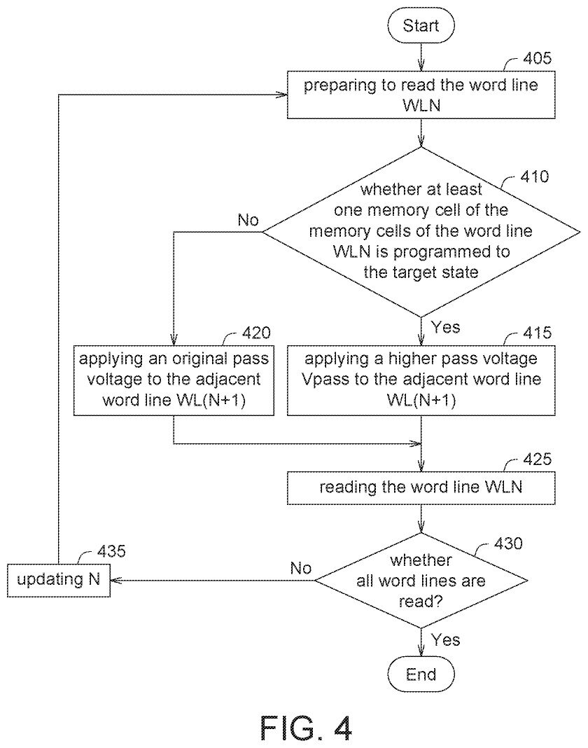

FIG. 4 shows a read operation method according to one embodiment of the application. In step 405, it is prepared to read the word line WLN (the target word line). In step 410, it is determined whether at least one memory cell of the memory cells of the word line WLN is programmed to a second target state, in here, the second target state is the A state. Whether at least one memory cell of the memory cells of the word line WLN is programmed to the second target state (A state) is based on the recorded programming states of the memory cells of all word lines.

If yes in step 410, then a higher pass voltage Vpass is applied to the adjacent word line WL(N+1) in step 415; and if no in step 410 (that is, none of the memory cells of the word line is programmed to the second target state), an original pass voltage is applied to the adjacent word line WL(N+1) in step 420.

In one embodiment of the application, in reading operations, applying a higher pass voltage to the adjacent word line WL(N+1) (when at least one memory cell of the memory cells of the word line WLN is programmed to the second target state) is to increase the over-drive voltage on the word line WL(N+1). This is because, if the over-drive voltage on the word line WL(N+1) is insufficient, then the word line interference on the erased-state cells of the word line WLN is significant. Thus, by increasing the over-drive voltage on the word line WL(N+1), the word line interference on the erased-state cells of the word line WLN is effectively reduced and improved.

In one embodiment of the application, in reading operations, applying an original pass voltage Vpass to the adjacent word line WL(N+1) (when none of the memory cells of the word line WLN is programmed to the second target state) is to prevent read disturbance.

In step 425, the word line WLN is read. In step 430, it is determined whether all word lines are read. If yes in step 430, then the flow ends. If no in step 430, the flow proceeds to the step 435. In step 435, N is updated (N=N+1) and the flow returns to the step 405 to read the next word line.

That is, in one embodiment of the application, in reading operations, based on whether at least one memory cell of the memory cells of the target word line WLN is programmed to the second target state (i.e. the A state), the pass voltage Vpass applied to the adjacent word line WL(N+1) is adjusted. When at least one memory cell of the memory cells of the target word line WLN is programmed to the second target state (i.e. the A state), the pass voltage Vpass applied to the adjacent word line WL(N+1) is increased. When none of the memory cells of the target word line WLN is programmed to the second target state (i.e. the A state), the pass voltage Vpass applied to the adjacent word line WL(N+1) is kept to be original.

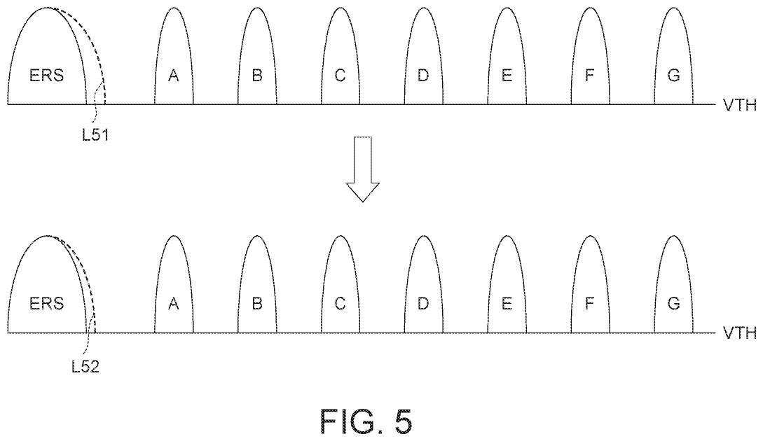

FIG. 5 shows threshold voltage distribution of triplelevel cells according to one embodiment of the application. The upper part in FIG. 5 refers to the threshold voltage distribution in the prior art, wherein the threshold voltage distribution of the erased-state cells (caused by the word line interference) is represented by the curve L51. The lower part in FIG. 5 refers to the threshold voltage distribution in one embodiment of the application, wherein the threshold voltage distribution of the erased-state cells (caused by the word line interference) is represented by the curve L52. By comparing the upper part with the lower part in FIG. 5, the word line interference on the erased-state cells is improved and thus in reading the memory cells, it is easy to correctly judge whether the memory cell is at the erased state or in the second target state (A state).

In one embodiment of the application, the reading operation method in FIG. 4 is applied both in the normal read operations and in the program-verify operations, which is in the spirit and scope of the application.

In one embodiment of the application, the programming operations in FIG. 2 and the reading operations in FIG. 4 may be implemented together. That is, the programming operations in FIG. 2 is used to program the memory cells in the memory device and the reading operations in FIG. 4 is used to read and/or program-verify the memory cells in the memory device.

Of course, in other possible embodiment of the application, the programming operations in FIG. 2 and the reading operations in FIG. 4 may be implemented independently, which is still within the spirit and the scope of the application.

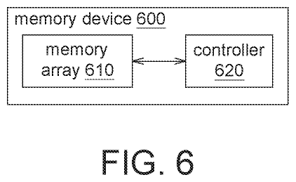

FIG. 6 shows a functional block of a memory device according to one embodiment of the application. The memory device 600 includes a memory array 610, including a plurality of memory cells and a plurality of word lines; and a controller 620, coupled to the memory array 610. The controller 620 is configured for performing the above operation methods in the above embodiments of the application. Details of the controller 620 is not repeated here.

As discussed above, embodiments of the application may effectively suppress the word line interference to correctly judge the readout data.

It will be apparent to those skilled in the art that various modifications and variations can be made to the disclosed embodiments, It is intended that the specification and examples be considered as exemplary only, with a true scope of the disclosure being indicated by the following claims and their equivalents.

What is claimed is:

1. An operation method for a memory device, comprising:
preparing to program a target word line;
judging whether at least one memory cell of a plurality of memory cells of an adjacent word line is to be programmed to a first target state; and
based on whether the at least one memory cell of the memory cells of the adjacent word line is to be programmed to the first target state, determining to program the adjacent word line first or to program the target word line first.

2. The operation method according to claim 1, wherein
when the at least one memory cell of the memory cells of the adjacent word line is to be programmed to the first target state, the adjacent word line is programmed earlier than the target word line.

3. The operation method according to claim 1, wherein
when none of the memory cells of the adjacent word line is to be programmed to the first target state, the target word line is programmed earlier than the adjacent word line.

4. The operation method according to claim 1, further including:
preparing to read the target word line;
determining whether at least one memory cell of a plurality of memory cells of the target word line is programmed to a second target state; and
based on whether the at least one memory cell of the memory cells of the target word line is programmed to the second target state, applying an original pass voltage or an increased pass voltage to the adjacent word line.

5. The operation method according to claim 4, wherein
when the at least one memory cell of the memory cells of the target word line is programmed to the second target state, applying the increased pass voltage to the adjacent word line; and
when none of the memory cells of the target word line is programmed to the second target state, applying the original pass voltage to the adjacent word line.

6. The operation method according to claim 4, wherein the operation method is is applied in a normal read operation or a program-verify operation.

7. An operation method for a memory device, including:
preparing to read a target word line;
determining whether at least one memory cell of a plurality of memory cells of the target word line is programmed to a target state; and
based on whether the at least one memory cell of the memory cells of the target word line is programmed to the target state, applying an original pass voltage or an increased pass voltage to an adjacent word line.

8. The operation method according to claim 7, wherein
when the at least one memory cell of the memory cells of the target word line is programmed to the target state, applying the increased pass voltage to the adjacent word line.

9. The operation method according to claim 7, wherein
when none of the memory cells of the target word line is programmed to the target state, applying the original pass voltage to the adjacent word line.

10. The operation method according to claim 7, wherein the operation method is applied in a normal read operation or a program-verify operation.

11. A memory device, comprising:
a memory array, including a plurality of memory cells and a plurality of word lines; and
a controller, coupled to the memory array,
wherein the controller is configured for:
preparing to program a target word line;
judging whether at least one memory cell of a plurality of memory cells of an adjacent word line is to be programmed to a first target state; and
based on whether the at least one memory cell of the memory cells of the adjacent word line is to be programmed to the first target state, determining to program the adjacent word line first or to program the target word line first.

12. The memory device according to claim 11, wherein
when the at least one memory cell of the memory cells of the adjacent word line is to be programmed to the first target state, the adjacent word line is programmed earlier than the target word line.

13. The memory device according to claim 11, wherein
when none of the memory cells of the adjacent word line is to be programmed to the first target state, the target word line is programmed earlier than the adjacent word line.

14. The memory device according to claim 11, wherein the controller is further configured for:
preparing to read the target word line;
determining whether at least one memory cell of a plurality of memory cells of the target word line is programmed to a second target state; and
based on whether the at least one memory cell of the memory cells of the target word line is programmed to the second target state, applying an original pass voltage or an increased pass voltage to the adjacent word line.

15. The memory device according to claim 14, wherein the controller is further configured for:
when the at least one memory cell of the memory cells of the target word line is programmed to the second target state, applying the increased pass voltage to the adjacent word line; and
when none of the memory cells of the target word line is programmed to the second target state, applying the original pass voltage to the adjacent word line.

16. The memory device according to claim 14, wherein the controller is configured for a normal read operation or a program-verify operation.
